(19) United States
(12) Patent Application Publication
(10) Pub. No.: US 2024/0266262 A1
(43) Pub. Date: Aug. 8, 2024

(54) CHIP-ON-CHIP POWER CARD HAVING EMBEDDED THERMAL CONDUCTOR

(71) Applicant: Toyota Motor Engineering & Manufacturing North America, Inc., Plano, TX (US)

(72) Inventors: Feng ZHOU, Ann Arbor, MI (US); Tianzhu FAN, Houston, TX (US)

(73) Assignee: Toyota Motor Engineering & Manufacturing North America, Inc., Plano, TX (US)

(21) Appl. No.: 18/106,779

(22) Filed: Feb. 7, 2023

(51) Int. Cl. H01L 23/495; H01L 25/07

(52) U.S. Cl. CPC H01L 23/49568; H01L 23/4951; H01L 23/49575; H01L 23/49579; H01L 23/49582; H01L 25/074; H01L 23/49513; H01L 23/49562; H01L 24/32; H01L 24/33; H01L 2224/32245; H01L 2224/33181

(57) ABSTRACT

A power card for use in a vehicle includes a N lead frame, a P lead frame, and an O lead frame. The O lead frame includes, in part, an embedded copper-graphite thermal conductor. Part of the O lead frame is located between the N lead frame and the P lead frame. A first power device is located on a first side of the O lead frame between the N lead frame and the O lead frame. A second power device being located on a second side of the O lead frame between the O lead frame and the P lead frame. The O lead frame is configured to receive heat from the first power device and the second power device and transfer the heat for heat dissipation.

### TECHNICAL FIELD

The present specification generally relates to a compact low inductance chip-on-chip power card, and, more specifically, an apparatus and system for a thermal conductor structure for heat transfer and cooling of a chip-on-chip power card.

### BACKGROUND

Modern vehicles use electricity as part of the operation of the vehicle. These vehicles may be operated using electricity exclusively, or by using a combination of electricity and another energy source. Many modern vehicles include a power control unit (PCU) configured to manage the energy amongst multiple different vehicle electrical systems. In the case of vehicles driven by electric motors, a power control unit may be used to control the electric motor, including torque and speed of the motor.

A component of the power control unit is a power card, which contains power devices that may be switched on and off in high frequency during operation of the vehicle. These power devices may generate significant amounts of heat. Conventional power cards have designs for exposing surface area of the power devices for cooling purposes. However, these conventional power cards are bulky and not useful in compact space contexts. Thus, there is a need for a power card capable of providing cooling while being a compact size.

### SUMMARY

In one embodiment, a power card for use in a vehicle includes a N lead frame, a P lead frame, an O lead frame, a first power device and a second power device. The O lead frame has in part an embedded copper-graphite thermal conductor and part of the O lead frame is located between the N lead frame and the P lead frame. The first power device is located on a first side of the O lead frame between the N lead frame and the O lead frame. The second power device is located on a second side of the O lead frame between the O lead frame and the P lead frame. The O lead frame is configured to receive heat from the first power device and the second power device and transfer the heat for heat dissipation.

In another embodiment, a power system includes a power card. The power card includes an O lead frame, a first power device and a second power device. The O lead frame has, in part, an embedded copper-graphite thermal conductor. Part of the O lead frame is located between a N lead frame and a P lead frame. The first power device is located on a first side of the O lead frame between the N lead frame and the O lead frame. The second power device is located on a second side of the O lead frame between the O lead frame and the P lead frame. The O lead frame is configured to receive heat from the first power device and the second power device and transfer the heat for heat dissipation.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a perspective view of a compact low inductance chip-on-chip power card, according to one or more embodiments described and illustrated herein;

FIG. 2 schematically depicts a side view of the compact low inductance chip-on-chip power card of FIG. 1, according to one or more embodiments described and illustrated herein;

FIG. 3 schematically depicts a side view of the compact low inductance chip-on-chip power card of FIG. 1, including the heat flow direction, according to one or more embodiments described and illustrated herein;

FIG. 4 schematically depicts a copper-graphite O lead frame, according to one or more embodiments described and illustrated herein;

FIG. 5 schematically depicts a side view of the compact low inductance chip-on-chip power card of FIG. 1, including embedded thermal conductor and the current direction, according to one or more embodiments described and illustrated herein;

FIG. 6 schematically depicts a side view of the compact low inductance chip-on-chip power card of FIG. 1, including embedded thermal conductor and cold plates, according to one or more embodiments described and illustrated herein; and

FIG. 7 schematically depicts O lead frame with three cooling surfaces, according to one or more embodiments described and illustrated herein.

### DETAILED DESCRIPTION

Embodiments described herein are generally directed a copper-graphite dual functional O Lead frame and thermal conductor structure to enhance the heat transfer and cooling performance of the chip-on-chip structure.

A power card may be a part of a power control unit of a vehicle. The power control unit is configured to manage the energy amongst multiple different vehicle electrical systems. In vehicles with electric motors, the power control unit may be responsible for operation of the electric motor. The power control unit may include a power card having power devices that are switched on and off at high frequencies during operations of the vehicle. These power devices may be any switch, such as an RC-IGBT, an IGBT/diode combination, or a MOSFET, for example.

The chip-on-chip power card design shows a large decrease in size and inductance compared to conventional power cards. As described in more detail below, the O lead frame, which serves as an output for one phase of the alternating current, can also be used to enhance the heat transfer from the power card to the cold plate with an embedded thermal conductor. In a system, the copper-graphite thermal conductor may work to decrease the temperature of the structure.

The power cards described herein may be used with a vehicle. The vehicle may have an automatic or manual transmission. The vehicle may be an electric vehicle, a hybrid vehicle, a plug-in hybrid vehicle, a fuel cell vehicle, or any other type of vehicle that includes a motor/generator. Further, the vehicle may be capable of non-autonomous operation or semi-autonomous operation or autonomous operation. That is, the vehicle may be driven by a human driver or may be capable of self-maneuvering and navigating without human input. A vehicle operating semi-autonomously or autonomously may use one or more sensors and/or a navigation unit to drive autonomously.

Various embodiments of chip-on-chip power card assemblies, and power systems are described in detail below. Whenever possible, the same reference numerals will be used throughout the drawings to refer to the same or like parts.

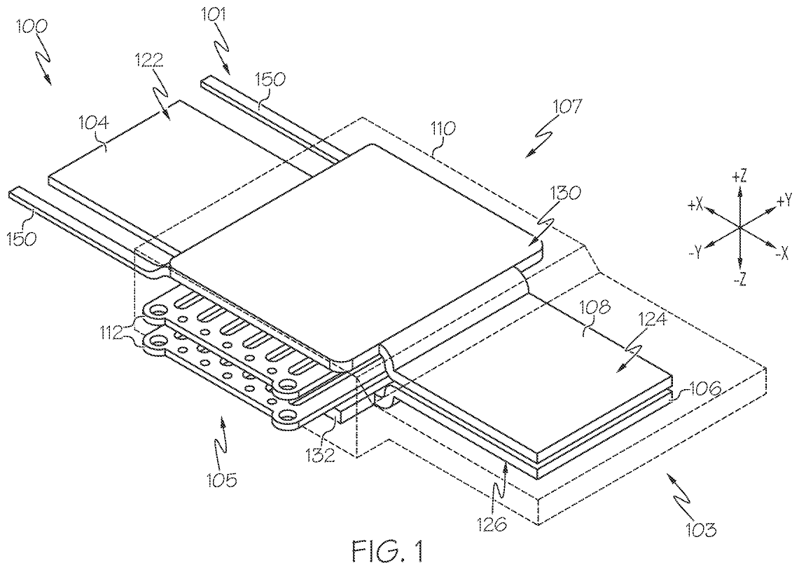

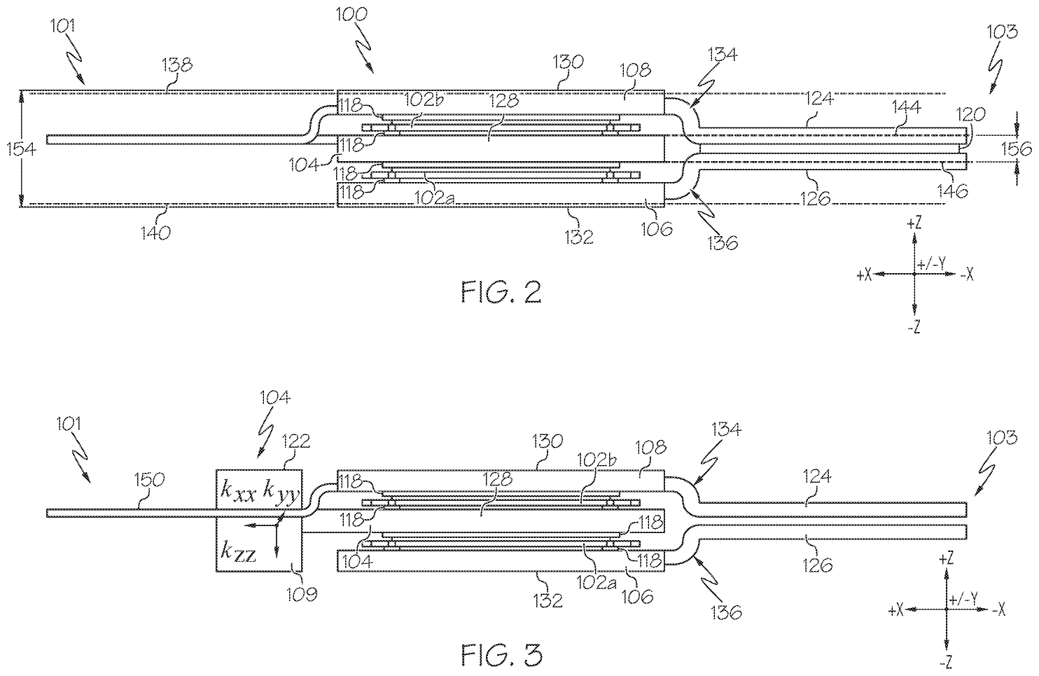

FIGS. 1 and 2 illustrates a chip-on-chip power card 100. The chip-on-chip power card 100 has a chip-on-chip design, where the power devices 102a, 102b are located in a vertically stacked arrangement. The power card includes a P lead frame 108, a soldering layer 118, a second power device 102b, a soldering layer 118, a O lead frame 104, a soldering layer 118, a first power device 102a, a soldering layer 118, and a N lead frame 106 stacked on each other in a substantially vertical direction. The O lead frame 104 includes an embedded copper-graphite thermal conductor 109 (shown in FIG. 3) to act with dual purpose as the output of the power card and to dissipate heat.

The chip-on-chip power card 100 includes the O lead frame 104 having a cooling portion 122 extending from a body portion 128 (shown in FIG. 2) towards a first end 101 of the chip-on-chip power card 100. The chip-on-chip power card 100 also includes an N lead frame 106 having a terminal portion 126 extending from a body portion 132 towards the second end 103 of the chip-on-chip power card 100. The chip-on-chip power card 100 also includes a P lead frame 108 having a terminal portion 124 extending from a body portion 130 towards the second end 103 of the chip-on-chip power card 100. The terminal portions 124, 126 are configured to connect to other vehicle components to connect the chip-on-chip power card 100 to the vehicle.

In some embodiments, the body portions of the lead frames may be referred to as the substrate. Electrical current flows from the terminal portion 124 of the P lead frame 108 to the terminal portion 126 of the N lead frame 106. The cooling portion 122 of the O lead frame 104 serves as an output. For example, when the chip-on-chip power card 100 is used in conjunction with multiple other power cards in an inverter, the terminal portion 124 of the P lead frame 108 and the terminal portion 126 of the N lead frame 106 of each power card may be connected to the DC power source, and the cooling portion 122 of the O lead frame 104 of each power card is responsible for outputting one phase of the alternating current, with the combined outputs of the terminal portions of the O lead frames of each power card creating an alternating current. The alternating current may be used to power a motor, for example. When the inverter is bi-directional, alternating current generated by regenerative braking, for example, could be received by the terminal portions of the O lead frames of the multiple power cards, and a DC battery may be recharged using the power cards.

The chip-on-chip power card 100 has a first end 101 and a second end 103 opposite the first end 101. The cooling portion 122 of the O lead frame is located at the first end 101 and the terminal portion 126 of the N lead frame and the terminal portion 124 of the P lead frame 108 are located at the second end 103. By being on opposite ends of the chip-on-chip power card 100, the terminal portions of the O lead frame 104, the N lead frame 106, and the P lead frame 108 may be as wide as the power device. In addition, by having the cooling portion 122 of the O lead frame 104 on the opposite end as the terminal portion 124 of the P lead frame 108 and the terminal portion 126 of the N lead frame 106, the terminal portion 124 of the P lead frame 108 and the terminal portion 126 of the N lead frame 106 may be located very close to each other and separated by a thin insulator. This close location to each other results in very low inductance for high-speed switching of the power devices.

The chip-on-chip power card 100 includes two sets of signal terminals 112, one set for each of the two power devices 102a, 102b. Each set of signal terminals 112 is connected to a respective power device 102a, 102b. The set of signal terminals 112 provides connections to the power device 102a, 102b, for purposes of providing switching signals to the power device 102a, 102b and also for purposes of detecting data from the power device 102a, 102b. For example, when there are 5 signal terminals in the set of signal terminals 112, one signal terminal may connected to the gate of the power device 102a, 102b and be used as a gate signal for switching the power device 102a. 102b on and off using low voltage, two signal terminals may be used for detecting temperature, one signal terminal may be used as a current sensor, and one signal terminal may be used as an emitter voltage sensor.

The chip-on-chip power card 100 also includes voltage terminals 150 as being part of the P lead frame 108. The voltage terminals 150 may be used to detect a voltage of the chip-on-chip power card 100. The voltage terminals 150 extend away from the body portion 130 of the P lead frame 108, but in a direction opposite the terminal portion 124 of the P lead frame 108. Thus, the voltage terminals 150 are located at the first end 101 of the chip-on-chip power card 100, alongside the cooling portion 122 of the O lead frame 104. The voltage terminals 150 may be located horizontally on either side of the cooling portion 122 of the O lead frame 104.

The chip-on-chip power card 100 has a first lengthwise edge 105 and a second lengthwise edge 107 opposite the first lengthwise edge 105. As shown in FIG. 1, the sets of signal terminals 112 are located at the first lengthwise edge 105 and the voltage terminals 150 are located at the first end 101. However, in some embodiments, the voltage terminals 150 may be removed and the sets of signal terminals 112 may be reduced to a single signal terminal corresponding to each power device, and these single signal terminals may be located horizontally on either side of the cooling portion 122 of the O lead frame 104, similar to the location of the voltage terminals 150 in FIG. 1.

The chip-on-chip power card 100 may be partially encased in resin 110. The resin 110 may be injection molded to the chip-on-chip power card 100 such that all gaps between the components of the chip-on-chip power card 100 are occupied with resin 110. The resin 110 may insulate the components of the chip-on-chip power card 100 to allow the chip-on-chip power card 100 to operate more efficiently. The cooling portion 122 of the O lead frame 104, the voltage terminals 150, portions of the sets of signal terminals 112, a portion of the terminal portion 124 of the P lead frame, and a portion of the terminal portion 126 of the N lead frame may not be covered in resin 110, with the remaining components of the chip-on-chip power card 100 being encased in resin 110. The exposed portion of the terminal portion 124 of the P lead frame may be the top surface of the terminal portion 124. The exposed portion of the terminal portion 126 of the N lead frame may be the bottom surface of the terminal portion 126.

FIG. 2 illustrates a side view of components of the chip-on-chip power card 100. The body portion 130 of the P lead frame 108 is aligned with the body portion 128 of the O lead frame 104 as well as the body portion 132 of the N lead frame 106. In addition, the first power device 102a is shown as being between the body portion 132 of the N lead frame 106 and the body portion 128 of the O lead frame 104. The second power device 102b is shown as being between the body portion 128 of the O lead frame 104 and the body portion 130 of the P lead frame 108. Soldering layers 118 are seen between the P lead frame 108 and the second power device 102B, between the second power device 102B and the O lead frame 104, the O lead frame 104 and the first power device 102a, and the first power device 102a and the N lead frame 106.

The terminal portion 124 of the P lead frame 108 is connected to the body portion 130 of the P lead frame 108 by a bend 134. The body portion 130 of the P lead frame lies along a P body plane 138 and the terminal portion 124 of the P lead frame 108 lies along a P terminal plane 144. The P body plane 138 and the P terminal plane 144 are parallel. The bend 134 brings the terminal portion 124 of the P lead frame 108 closer to the N lead frame 106.

The terminal portion 126 of the N lead frame 106 is connected to the body portion 132 of the N lead frame 106 by a bend 136. The body portion 132 of the N lead frame lies along an N body plane 140 and the terminal portion 126 of the N lead frame 106 lies along an N terminal plane 146. The N body plane 140 and the N terminal plane 146 are parallel. The bend 136 brings the terminal portion 126 of the N lead frame 106 closer to the P lead frame 108.

The distance 154 between the body portion 130 of the P lead frame 108 and the body portion 132 of the N lead frame 106 is greater than the distance 156 between the terminal portion 124 of the P lead frame 108 and the terminal portion 126 of the N lead frame 106 due to the bends 134, 136.

An insulator 120 may be located between the terminal portion 124 of the P lead frame 108 and the terminal portion 126 of the N lead frame 106. The voltage difference between the terminal portion 124 of the P lead frame 108 and the terminal portion 126 of the N lead frame 106 is relatively high. The insulator 120 may be configured to assist in reducing inductance between the P terminal and the N terminal. The insulator 120 may span the entire length of the terminal portion 124 of the P lead frame 108 and the terminal portion 126 of the N lead frame 106, or may occupy a portion thereof. The insulator 120 may be made of ceramic or any other insulating material. The insulator 120 may be very thin-approximately 320 μm thick. The insulator 120 may occupy the entire distance 156 between the terminal portion 124 of the P lead frame 108 and the terminal portion 126 of the N lead frame 106.

The body portion 128 of the O lead frame 104 has a top surface that lies along an O plane 142. The cooling portion 122 of the O lead frame 104 may also lie along the O plane 142 such that a top surface of the body portion 128 of the O lead frame is coplanar to a top surface of the cooling portion 122 of the O lead frame 104.

The voltage terminals 150 of the P lead frame 108 may extend in a direction opposite the terminal portion 124 of the P lead frame 108. The voltage terminals 150 may be connected to the body portion 130 of the P lead frame 108 by a bend, and the voltage terminals 150 may lie along the O plane 142.

FIG. 3 illustrates an O lead frame 104 including an embedded copper-graphite thermal conductor 109. The thermal conductivity of graphite is not homogeneous. Graphite has high thermal conductivity in two axes, but low thermal conductivity along a third axis. The thermal conductivity properties of the O lead frame 104 is shown on the 3-dimensional axes as kxx, kyy, and kzz. The thermal conductivity along the lengthwise axis of the O lead frame is represented by kxx. The thermal conductivity along the widthwise axis of the O lead frame 104 is represented by kyy. The thermal conductivity along the vertical axis of the O lead frame 104 is represented by kzz.

In embodiments, the O lead frame 104 may be made so that the two axes of the graphite with high thermal conductivity are kxx and kzz and the axis with low thermal conductivity is kyy. In other embodiments, the O lead frame 104 may be made so that the two axes of the graphite with high thermal conductivity are kyy and kzz and the axis with low thermal conductivity is kxx or so that the two axes of the graphite with high thermal conductivity are kxx and kyy and the axis with low thermal conductivity is kzz.

In embodiments, the embedded copper-graphite thermal conductor 109 is made of an interior of thermal polytropic graphite. The thermal polytropic graphite is covered with a copper shell. In embodiments, the copper shell has a thickness between 0.05 mm and .mm. In other embodiments, the Copper shell has a thickness between .mm and 0.3M. The embedded copper-graphite thermal conductor 109 may be on the top side of the O lead frame 104. However, it should be understood that the embedded copper-graphite thermal conductor 109 may be added on all sides of the O lead frame 104, except the N lead frame 106 and P lead frame 108 terminal sides. In some embodiments, the embedded copper-graphite thermal conductor 109 may be embedded on only part of the O lead frame.

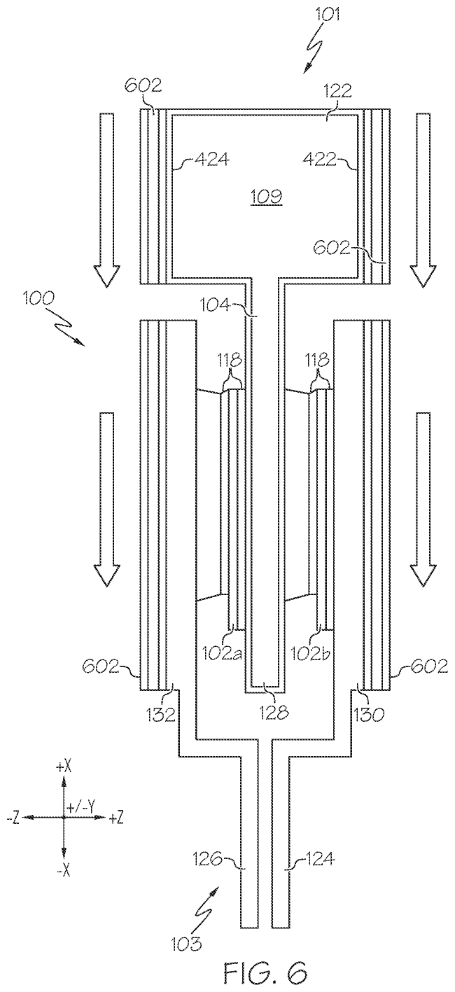

Thermal polytropic graphite has a greater thermal conductivity then copper. As a result, when the power devices 102a, 102b generate heat unevenly, the uneven heat is spread across the copper of the embedded copper-graphite thermal conductor 109 to reach the thermal polytropic graphite of the embedded copper-graphite thermal conductor 109. The heat is then directed as described below to the cooling portion 122 of the O lead frame 104 and on to cooling devices 602 (FIG. 6).

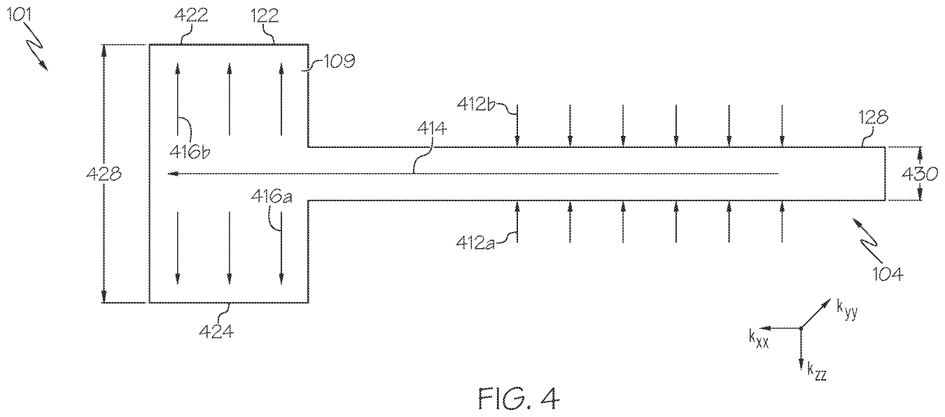

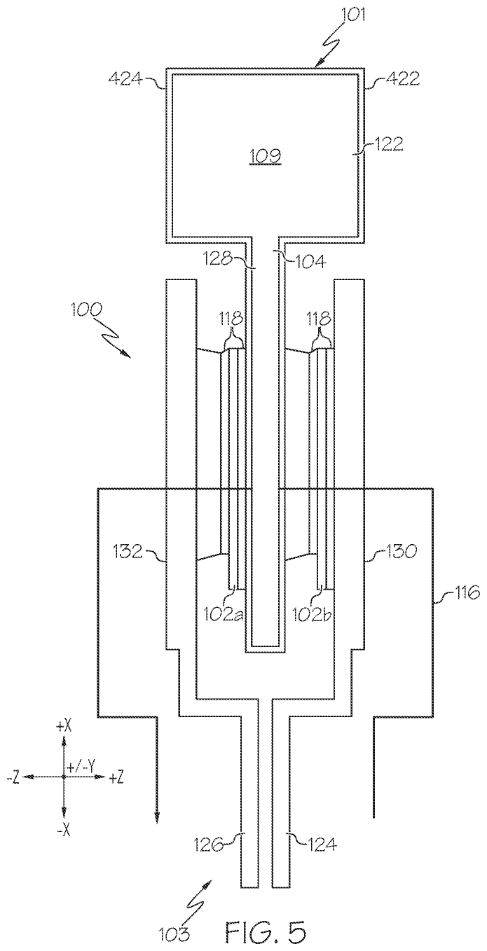

As shown in FIG. 4, heat 412a received by the body portion 206 of the O lead frame 104 from the first power device 102a and the heat 412b received by the body portion 128 of the O lead frame 104 from the second power device 102b are easily absorbed by the embedded copper-graphite thermal conductor 109 of the O lead frame 104 (along the kzz axis). The heat 414 is efficiently directed toward the cooling portion 122 (along the kxx axis) which is cooler than the body portion 128 towards the first end 101 of the chip-on-chip power card 100. The heat 416a is then directed (along the kzz axis) to the bottom surface 424 (or attached cooling device, as seen in FIG. 6) and the heat 416b is directed (along the kzz axis) to the top surface 422 (or attached cooling device, as seen in FIG. 6). The heat 414 may also continue to the side surfaces 426 (along the kxx axis).

A thickness 428 of the cooling portion 122 may be greater than a thickness 430 of the body portion 128 of the O lead frame 104. The increased thickness and the greater surface area described herein contribute to the cooling capabilities of the cooling portion 122. In embodiments, the thickness 428 of the cooling portion 122 may be between 125% and 300% the thickness 430 of the body portion 128. In other embodiments, the thickness 428 of the cooling portion 122 may be between 125% and 300% the thickness 430 of the body portion 128. The greater volume of thermal conductor allows for greater heat dissipation, however, the total volume of the chip-on-chip power structure is increased.

FIG. 5 depicts a the compact low inductance chip-on-chip power card 100 with the embedded copper-graphite thermal conductor 109 and the electrical current 116 direction. The electrical current 116 travels from the terminal portion 124 of the P lead frame 108 through body portion 130 of the P lead frame 108 and through the two power devices 102a, 102b. The electrical current then flows through the body portion 132 of the N lead frame 106 and into the terminal portion 126 of the N lead frame 106. The electrical current 116 travels in strait line through the chip-on-chip power card 100, making the chip-on-chip power card 100 more efficient than traditional power cards. Electrical current 116 flows from the P lead frame 108 to the power devices 102a, 102b, and through the N lead frame 106. The O lead frame 104 serves as an output.

As descried above, FIG. 6 depicts attached cooling devices 602 to the chip-on-chip power card 100. These cold plates are adjacent to the bottom surface 424 and the top surface 422 of the embedded copper-graphite thermal conductor 109 of the cooling portion 122 to absorb the heat 416a, 416b. In embodiments, these devices may be cold plates. The cooling devices 602 may be any device capable of removing heat flux from the chip-on-chip power card 100. Non-limiting examples for the cooling device 602 include cold plates, heat sinks, single-phase liquid cooling, two-phase liquid cooling, and vapor chambers.

As an example, in embodiments of a power system for an inverter of 80 KW, the copper-graphite embedded thermal conductor 109 in a chip-on-chip power card 100 may the temperature by greater than 10 degrees compared to the chip-on-chip power card with no thermal conductor. In other embodiments, the copper-graphite embedded thermal conductor 109 in a chip-on-chip power card 100 may the temperature by greater than 15 degrees compared to the chip-on-chip power card with no thermal conductor. Further, copper-graphite embedded thermal conductor 109 in a chip-on-chip power card 100 may the temperature by greater than 5 degrees compared to the chip-on-chip power card with a single coper thermal conductor.

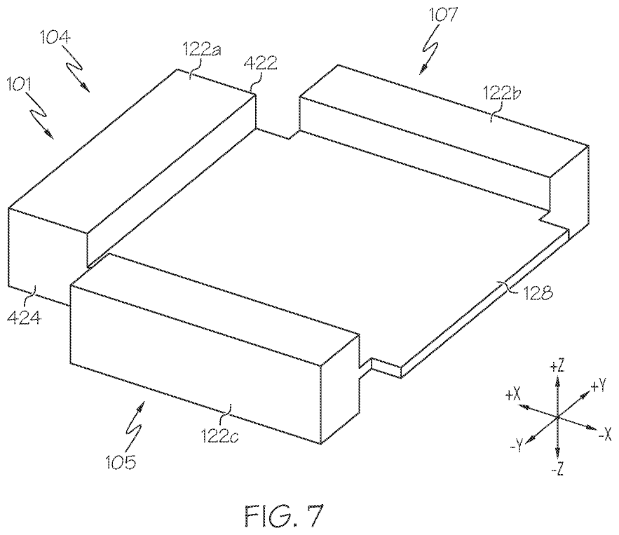

In some embodiments, the copper-graphite embedded thermal conductor 109 increases the total volume of the chip-on-chip between 40% and 60%. In other embodiments, the copper-graphite embedded thermal conductor 109 increases the total volume of the chip-on-chip by greater that 50%. In these embodiments, the temperature can be further decreased by adding the embedded copper-graphite thermal conductor 109 to other sides of the O lead frame 104 as seen below in FIG. 7, however, this increases the volume of the chip-on-chip power card 100.

FIG. 7 illustrates an O lead frame 104 having a body portion 128 and multiple cooling portions 122a, 122b, 122c extending from the body portion 128. In particular, a first cooling portion 108a extends along the length of the power card that the O lead frame 104 is used in towards the first end 101 of the chip-on-chip power card 100. A second cooling portion 122b extends in a first side direction along the width of the power card along the second lengthwise edge 107. A third cooling portion 122c extends in a second side direction along the width of the power card along the first lengthwise edge 105. Thus, the second cooling portion 122b and the third cooling portion 122c may be on opposite sides of the body portion 128 of the O lead frame 104, and may each extend in directions perpendicular to the direction the first cooling portion 122a extends in.

The additional cooling portions 122a, 122b, 122c of the O lead frame 104 may allow the O lead frame 104 to more efficiently dissipate heat generated by the power devices. In embodiments, the O lead frame 104 may be used with power cards that do not have a set of signal terminals on the side of the power card. While three discrete cooling portions are illustrated in FIG. 7, in some embodiments, there may be more cooling portions (e.g., 6 cooling portions, 9 cooling portions, etc.) or there may be one continuous cooling portion spanning a perimeter of the O lead frame 104 on three sides of the body portion 128.

In some embodiments, the cooling portions 122a, 122b, 122c may be referred to as terminal portions. Except as noted herein, any of the components of any embodiment described herein may be used with any other embodiment. The embodiments described and illustrated are non-limiting.

From the above, it is to be appreciated that defined herein are power systems and assemblies. Specifically, the power systems with a power card assembly disclosed herein include a power card with a chip-on-chip design, where the power devices are located in a substantially vertical stacked arrangement of a P lead frame, a soldering layer, a power device, a soldering layer, a O lead frame, a soldering layer, a power device, a soldering layer, and a N lead frame. The O lead frame includes an embedded thermal conductor configured to act with dual purpose as the output of the power card and to transfer heat for heat dissipation.

It should now be understood that embodiments of the present disclosure are directed a dual functional O lead frame and with embedded copper-graphite thermal conductor structure to enhance the heat transfer and cooling performance of the chip-on-chip structure configured to manage the energy amongst multiple different vehicle electrical systems.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

It will be apparent to those skilled in the art that various modifications and variations can be made to the embodiments described herein without departing from the scope of the claimed subject matter. Thus, it is intended that the specification cover the modifications and variations of the various embodiments described herein provided such modification and variations come within the scope of the appended claims and their equivalents.

What is claimed is:

1. A power card for use in a vehicle, the power card comprising:
a N lead frame;
a P lead frame;
an O lead frame comprising in part an embedded copper-graphite thermal conductor, part of the O lead frame being located between the N lead frame and the P lead frame;
a first power device being located on a first side of the O lead frame between the N lead frame and the O lead frame; and
a second power device being located on a second side of the O lead frame between the O lead frame and the P lead frame, the O lead frame configured to receive heat from the first power device and the second power device and transfer the heat for heat dissipation.

2. The power card of claim 1, wherein
the N lead frame comprises a body portion and a terminal portion, the terminal portion extending outward from the body portion; and
the P lead frame comprises a body portion and a terminal portion, the terminal portion extending outward from the body portion.

3. The power card of claim 2, wherein the O lead frame includes a body portion and a cooling portion, the cooling portion extending from the body portion such that the body portion of the P lead frame and the body portion of the N lead frame are non-overlapping with the cooling portion.

4. The power card of claim 3, wherein
the first power device being located between the body portion of the N lead frame and the body portion of the O lead frame; and
the second power device being located between the body portion of the O lead frame and the body portion of the P lead frame, the body portion of the O lead frame configured to receive the heat from the first power device and the second power device and transfer the heat for heat dissipation.

5. The power card of claim 4, wherein the terminal portion of the P lead frame and the terminal portion of the N lead frame lie along respective parallel planes, such that current flow through the P lead frame is parallel to current flow through the N lead frame.

6. The power card of claim 1, wherein the embedded copper-graphite thermal conductor has a higher thermal conductivity along a first axis and a second axis than along a third axis, the first axis, the second axis, and the third axis being perpendicular to each other.

7. The power card of claim 6, wherein the first axis is a vertical axis, the second is a lengthwise axis, and the third axis is a widthwise axis.

8. The power card of claim 7, wherein the embedded copper-graphite thermal conductor includes a thermal polytropic graphite.

9. The power card of claim 8, wherein the thermal polytropic graphite is at least partly covered with a copper shell.

10. The power card of claim 9, wherein the copper shell is 0.2 mm.

11. A power system comprising:
a power card having:
an O lead frame comprising in part an embedded copper-graphite thermal conductor, part of the O lead frame being located between a N lead frame and a P lead frame;
a first power device being located on a first side of the O lead frame between the N lead frame and the O lead frame; and
a second power device being located on a second side of the O lead frame between the O lead frame and the P lead frame, the O lead frame configured to receive heat from the first power device and the second power device and transfer the heat for heat dissipation.

12. The power system of claim 11, wherein
the N lead frame comprises a body portion and a terminal portion, the terminal portion extending outward from the body portion; and
the P lead frame comprises a body portion and a terminal portion, the terminal portion extending outward from the body portion.

13. The power system of claim 12, wherein the O lead frame includes a body portion and a cooling portion, the cooling portion extending from the body portion such that the body portion of the P lead frame and the body portion of the N lead frame are non-overlapping with the cooling portion.

14. The power system of claim 13, wherein
the first power device being located between the body portion of the N lead frame and the body portion of the O lead frame; and
the second power device being located between the body portion of the O lead frame and the body portion of the P lead frame, the body portion of the O lead frame configured to receive the heat from the first power device and the second power device and transfer the heat for heat dissipation.

15. The power system of claim 14, wherein the terminal portion of the P lead frame and the terminal portion of the N lead frame lie along respective parallel planes, such that current flow through the P lead frame is parallel to current flow through the N lead frame.

16. The power system of claim 11, wherein the embedded copper-graphite thermal conductor has a higher thermal conductivity along a first axis and a second axis than along a third axis, the first axis, the second axis, and the third axis being perpendicular to each other.

17. The power system of claim 16, wherein the first axis is a vertical axis, the second is a lengthwise axis, and the third axis is a widthwise axis.

18. The power system of claim 17, wherein the embedded copper-graphite thermal conductor includes a thermal polytropic graphite.

19. The power system of claim 18, wherein the thermal polytropic graphite is at least partly covered with a copper shell.

20. The power system of claim 19, wherein the copper shell is 0.2 mm.
